(19) United States
(12) Patent Application Publication
(10) Pub. No.: US 2024/0113037 A1
(43) Pub. Date: Apr. 4, 2024

(54) Package having component carrier with cavity and electronic component as well as functional filling medium therein

(71) Applicant: AT&S Austria Technologie & Systemtechnik AG, Leoben (AT)

(72) Inventors: Gerald Weis, Bruck an der Mur (AT); Janagan Papperi Devarajulu Deenadayalan, Leoben (AT)

(21) Appl. No.: 18/479,944

(22) Filed: Oct. 3, 2023

(30) Foreign Application Priority Data
Oct. 4, 2022 (DE) 10 2022 125 554.9

(51) Int. Cl. H01L 23/552; H01L 21/48; H01L 21/56; H01L 23/00; H01L 23/29; H01L 23/31; H01L 23/367; H01L 23/498

(52) U.S. Cl. CPC H01L 23/552; H01L 21/4857; H01L 21/56; H01L 23/295; H01L 23/3121; H01L 23/3672; H01L 23/49838; H01L 24/16; H01L 24/48; H01L 24/73; H01L 2224/16227; H01L 2224/48227; H01L 2224/73204

(57) ABSTRACT

A package includes a component carrier having a stack with at least one electrically conductive layer structure and/or at least one electrically insulating layer structure, a cavity in the stack, an active electronic component in the cavity, and a functional filling medium filling at least part of the cavity. The functional filling medium extends to an external surface of the stack for defining an output surface and configured to transmit at least one output of the active electronic component toward the output surface.

### CROSS-REFERENCE TO RELATED APPLICATIONS

This application claims priority of the filing date of German Patent Application No. 10 2022 125 554.9, filed Oct. 4, 2022, the disclosure of which is incorporated herein by reference in its entirety.

### TECHNICAL FIELD

Embodiments of the disclosure relate to a package and a method of manufacturing a package.

### BACKGROUND ART

In the context of growing product functionalities of component carriers equipped with one or more components and increasing miniaturization of such components as well as a rising number of components to be connected to the component carriers such as printed circuit boards, increasingly more powerful array-like components or packages having several components are being employed, which have a plurality of contacts or connections, with ever smaller spacing between these contacts. In particular, component carriers shall be mechanically robust and electrically reliable so as to be operable even under harsh conditions.

Conventional approaches of forming a package, which includes an electronic component, have a high complexity and a high space consumption.

### SUMMARY

There may be a need to form a compact package with a high degree of functionality and in a simple way.

According to an exemplary embodiment of the present disclosure, a package is provided which comprises a component carrier comprising a stack with at least one electrically conductive layer structure and/or at least one electrically insulating layer structure, a cavity in the stack, an active electronic component in the cavity, and a functional filling medium filling at least part of the cavity, said functional filling medium (in particular extending up to an external surface of the stack for) defining an output surface and configured to transmit at least one output of said active electronic component toward said output surface.

According to another exemplary embodiment of the present disclosure, a method of manufacturing a package is provided, wherein the method comprises providing a component carrier comprising a stack with at least one electrically conductive layer structure and/or at least one electrically insulating layer structure, forming a cavity in the stack, arranging an active electronic component in the cavity, and filling at least part of the cavity with a functional filling medium, said functional filling medium (in particular extending up to an external surface of the stack for) defining an output surface and configured to transmit at least one output of said active electronic component toward said output surface.

### Overview of Embodiments

In the context of the present application, the term “package” may particularly denote a device having one or more components (such as a semiconductor die) mounted on a support structure, in particular the component carrier, and being electrically connected in the package.

In the context of the present application, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. A component carrier may comprise a laminated stack, such as a laminated layer stack. In particular, a component carrier may be one of a printed circuit board, an organic interposer, and an IC (integrated circuit) substrate. A component carrier may also be a hybrid board combining different ones of the above-mentioned types of component carriers.

In the context of the present application, the term “stack” may particularly denote a flat or planar sheet-like body. For instance, the stack may be a layer stack, in particular a laminated layer stack or a laminate. Such a laminate may be formed by connecting a plurality of layer structures by the application of mechanical pressure and/or heat.

In the context of the present application, the term “layer structure” may particularly denote a continuous layer, a patterned layer, or a plurality of non-consecutive islands within a common plane.

In the context of the present application, the term “cavity” may particularly denote a blind hole or a through hole in the stack of the component carrier shaped and dimensioned for accommodating an active electronic component entirely or partially therein. Thus, an active electronic component may be entirely or partially accommodated in the cavity. Preferably, only one blind hole is formed in the cavity.

In the context of the present application, the term “active electronic component” may particularly denote a member fulfilling a task as part of an electronic circuit that relies on an external power source to control or modify electrical signals. Active electronic components, such as transistors and silicon-controlled rectifiers, may use electricity to control electricity. Further examples of active electronic components are diodes, thyristors, field effect transistors (FETs), MOSFETs, JFETs, optoelectronic members, and oscillators. Active components may be able to inject power into a circuit and may be capable of electrically controlling and/or amplifying the flow of electrical current. For instance, the active electronic component may be a semiconductor chip comprising a semiconductor material, in particular as a primary or basic material. The semiconductor material may for instance be a type IV semiconductor such as silicon or germanium or may be a type III-V semiconductor material such as gallium arsenide and/or indium phosphide. In particular, the chip may be a bare die or a molded die. At least one integrated circuit element may be monolithically integrated in such a chip.

In the context of the present application, the term “component in the cavity” may particularly denote a component being fully accommodated or only partially accommodated in the cavity in the stack. In a fully accommodated embodiment, the entire vertical spatial range between upper end and lower end of the component is located inside of the cavity. In a partially accommodated embodiment, only part of a vertical spatial range between upper end and lower end of the component is located inside of the cavity, for instance the component may protrude upwardly and/or downwardly beyond the cavity. In one embodiment, the upper end of the at least partially accommodated component may be in alignment with an upper main surface of the stack and/or the lower end of the component may be in alignment with a lower main surface of the stack.

In the context of the present application, the term “filling at least part of the cavity with a functional filling medium” may particularly denote a process of inserting a functional filling medium into at least part of the cavity. For instance, only a bottom portion, only a top portion, only a vertically intermediate portion, or only a lateral or a circumferential portion of the cavity may be filled with a filling medium so that a void remains in the cavity. It may also be possible that the entire cavity shall be filled with a filling medium so that no void remains in the cavity. It is also possible that not only the cavity, but also a portion protruding beyond the cavity shall be filled with a filling medium.

In the context of the present application, the term “functional filling medium” may particularly denote a material which is inserted in at least part of the cavity accommodating the electronic component, preferably with direct physical contact with the electronic component and the stack and provides at least one function. For example, a function provided by the functional filling medium may be an enhancement of the thermal conductivity, a reduction of a mismatch of the coefficient of thermal expansion inside of the component carrier, an electromagnetic shielding and/or guiding function for shielding and/or guiding electromagnetic radiation, a dielectric protection of the component, and/or a mechanical protection of the component. Such a filling medium may be at least partially electrically insulating (for instance may comprise epoxy resin or electrically insulating ink), at least partially electrically conductive (for instance may comprise metallic paste), at least partially magnetic (for example magnetic paste), at least partially optically transparent (in particular for visible light), etc. Upon application, the functional filling medium may be liquid or viscous and may be subsequently hardened by curing.

In the context of the present application, the term “external surface of the stack” may particularly denote all exterior surface portions of the stack accommodating the active electronic component and being filled with the functional filling medium. Said external surface of the stack including component and filling medium may define the entire outline thereof. In particular, said external surface of the stack may encompass an exposed surface of the functional filling medium provided at least partially in the stack cavity. For example, said external surface may be in alignment with the external main surface of the stack (see for instance FIG. 1). However, it is also possible that said external surface is vertically retracted with respect to the external main surface of the stack in which the cavity is formed (for instance so that an external recess remains between upper main surface of the stack and the external surface defined by the functional filling medium). In yet another alternative, said external surface may vertically protrude beyond the external main surface of the stack in which the cavity is formed (see for instance FIG. 8).

In the context of the present application, the term “output surface” may particularly denote an exterior surface portion of the functional filling medium at which at least one output is provided. Thus, the functional filling medium may provide a dedicated function and may deliver a corresponding output thereof to the output surface for removing (for instance dissipated heat from the component) the output out of the package and/or for providing (for instance an optical signal created by the component) the output to a destination body (wherein the latter may or may not form part of the package). At the output surface, the provided functional output of the functional filling medium may be input to a connected entity which may make use of said functional output. Said output surface may be brought in direct physical contact with another body. It is also possible that said output surface is functionally coupled with a wireless interface or forms part of a wireless interface, for instance for transmitting electromagnetic radiation. Thus, the output surface of the functional filling medium can be in contact with a further body, for example a heat sink, or can be an exposed surface, for instance for light transmission. In an embodiment, the output surface is flush with or forms a common plane with the external surface of the stack.

In the context of the present application, the term “at least one output” may particularly denote a signal provided by the electronic component and transmitted by the functional filling medium (for instance an optoelectronic optical signal) or an exhaust medium provided by the electronic component and conveyed by the functional filling medium (such as heat to be dissipated). For instance, heat of the component, light, etc., may be provided as at least one output.

In the context of the present application, the term “main surface of a body” may particularly denote one or more largest substantially planar surface area(s) of the body. Usually, for instance substantially cuboid bodies may have two opposing main surfaces in the form of two horizontal surface areas on top and on bottom of the body. Thus, the main surface may be different from the sidewalls of the body.

According to an exemplary embodiment of the present disclosure, a package is provided with a component carrier (such as a printed circuit board) having a (preferably laminated) layer stack. At least one (or more than one) active electronic component may be assembled in a cavity formed in the stack. Advantageously, a functional filling medium may fill at least part of the remaining volume of the cavity and may preferably also encapsulate the at least one electronic component. However, said functional filling medium may provide at least one additional function in addition to the encapsulation of the at least one component. For example, the functional filling medium may be made of a highly thermally conductive material enabling a heat removal (or even a spatially controlled heat spreading) from the component during operation of the package. In another embodiment, the functional filling medium may provide a signal conveying function, for instance may be at least partially optically transparent for enabling optical signal transmission through the functional filling medium. In accordance with said at least one additional function, the functional filling medium may define an output surface of the filled cavity, or at least part thereof. Via said output surface, the filling medium may supply or transmit at least one output (such as dissipated heat or transmitted optical signals, in the two above examples) of said active electronic component toward said output surface, for instance for further use or for dissipation. Advantageously, the mentioned configuration may provide a compact package, since the encapsulation of the component inside of the cavity may keep in particular the vertical dimension of the package low. Furthermore, the provision of the functional filling medium with its output surface for providing an output of the active electronic component may lead to a high degree of functionality of the package as a whole. Furthermore, forming a cavity and embedding the component in the cavity as well as filling functional filling medium in the cavity may allow to obtain the above-mentioned advantages in a simple way.

In the following, further exemplary embodiments of the package and the method will be explained.

In an embodiment, the electronic component is entirely embedded in the functional filling medium. Hence, the electronic component may be circumferentially surrounded by material of the functional filling medium, wherein one or more electric terminals (such as pads) of the electronic component may be electrically connected regardless of the entire embedding in the functional filling medium. By a full encapsulation in the functional filling medium, the electronic component may be properly mechanically and electrically protected around its entire circumference. When the functional filling medium is thermally conductive, dissipation of heat generated by the electronic component during operation of the package may be promoted by the surrounding functional filling medium as well.

In another embodiment, only a part of a surface of the at least one active electronic component is in direct physical contact with the functional filling medium, whereas another portion of the electronic component may remain exposed. For example, the functional filling medium may comprise a sheet arranged in an upper portion of the cavity above the electronic component arranged in a lower portion of the cavity. Such a sheet may cover a top side of the electronic component for protecting the electronic component and for providing the at least one additional function (for instance efficient heat dissipation) of the functional filling medium at the top side. For instance, the top side may be the side of the electronic component at which a major portion of heat is dissipated through the sheet-type functional filling medium towards a connected heat sink or directly to an exterior of the package. When the top side of the electronic component is covered by a sheet-type functional filling medium, it is also possible that another surface portion of the electronic component (for instance a bottom portion thereof) is in direct physical contact with another part of the functional filling medium, which may be made of the same material as or another material than the sheet. In this way, the function of the functional filling medium may be refined and may be selectively provided where needed.

In an embodiment, the functional filling medium is thermally conductive. This may mean that the functional filling medium may have a thermal conductivity significantly exceeding that of conventional encapsulant material. In particular, the functional filling medium may have a value of the thermal conductivity in a range from 2 W/m·K to 150 W/m·K, in particular in a range from 4 W/m·K to 20 W/m·K. By such a highly thermally conductive material, the functional filling medium may provide the additional function of removing a significant amount of heat generated by the connected electronic component through the functional filling medium out of the package. This may reduce the stress which may enhance the mechanical integrity and may reduce undesired phenomena such as delamination and warpage. In addition to promoting heat removal, the filling medium in a correspondingly dimensioned cavity may also contribute to heat spreading, i.e., removing heat (over a in particular frustoconical spatial range) in a controlled way.

In an embodiment, the functional filling medium comprises a matrix with filler particles embedded therein. For example, the matrix may be an initially adhesive material (such as a resin, preferably an epoxy resin) which may be cured during the manufacturing process so as to integrally hold together the different elements of the package. The filler particles may be selected and configured to provide an additional function to the functional filling medium. Thus, the filler particles may be selected in accordance with a function to be provided. For example, thermally highly conductive filler particles (such as ceramic particles, which may be made for example of aluminum nitride, aluminum oxide and/or silicon oxide) can be added to enhance the thermal conductivity of the functional filling medium as a whole. Thus, the selection of appropriate filler particles may allow to properly design the one or more functions provided by this functional filling medium as a whole. For instance, the functional filling medium may comprise an amount of filler particles in a range from 10 weight percent to 98 weight percent, in particular in a range from 50 weight percent to 95 weight percent, in relation to the entire volume of the functional filling medium.

In an embodiment, the filler particles comprise a metallic material, in particular a metallic core covered by a dielectric shell. The entirely metallic filler particles or the metallic core of such filler particles may provide excellent thermal conductivity for promoting heat removal. Additionally or alternatively, a metallic core may function for shielding electromagnetic radiation (such as radiofrequency) from propagating from the at least one active electronic component to an exterior of the package or to an optional other electronic component of the package, and/or from an exterior of the package to the at least one active electronic component in an interior thereof. Hence, a function provided by a corresponding functional filling medium may be an electromagnetic shielding function. An optional dielectric shell of the metallic filler particles may provide the filler particles as of whole with an overall electrically insulating property so that the functional filling medium may ensure a dielectric protection of the active electronic component regardless of the metallic cores.

In an embodiment, the functional filling medium is dielectric. Consequently, the functional filling medium may protect the encapsulated active electronic component from any undesired electric current flow and may help to avoid undesired electrically conductive paths in an interior of the package. When a plurality of electronic components, and in particular a plurality of active electronic components, are assembled in the cavity of the stack and/or in different cavities of the stack, the dielectric functional filling medium may ensure a reliable electric decoupling between said electronic components. Thus, the electric reliability of the package as a whole may be improved by a dielectric functional filling medium.

In an embodiment, the package comprises a thermal interface material (TIM) interacting with the output surface (in particular being attached to the output surface) of the functional filling medium and/or being arranged on an exterior surface of the stack. In the context of the present application, the term “thermal interface material” may in particular denote a thermally highly conductive (and preferably electrically insulating) material inserted between the functional filling medium and a connected body (such as a heat sink). Thus, the thermal interface material may serve for enhanced heat dissipation when being inserted between a heat-producing device (in particular the active electronic component being preferably in direct physical contact with the functional filling medium) and a heat-dissipating device (for instance a heat sink attached to the output surface with the thermal interface material in between). For example, thermal interface material may be embodied as a thermal paste, a thermal adhesive, a thermal gap filler, a thermally conductive pad, etc. in particular, the heat generated during the operation of a power semiconductor device package should be removed efficiently in order to ensure the safe operation and high-power density of the device. A simultaneous decrease in size of the electronic devices and increase in performance requirements pose difficulties in thermal management. Inefficient thermal management ultimately results in several failure mechanisms that can lead to degradation of the component(s). For many electronic applications, especially in the field of power electronics, it may be insufficient to just transfer the heat generated by the electronic component(s) to the ambient air via the printed circuit board. Instead, additional cooling of the component(s) may be advantageous, which can be achieved using an external, active, or passive cooled heat sink. A thermal interface material may serve as the interface between a printed circuit board-type component carrier with functional filling medium in a cavity thereof and a heat sink. In particular, such a thermal interface material (TIM) may reduce or even eliminate interstitial air gaps in the interface by conforming to the rough and uneven mating surfaces. A TIM may provide efficient heat dissipation and may prevent local temperature overloads resulting in reliable and stable operation of the electronic component(s). Such a TIM may be highly advantageous in particular in automotive power electronics, microelectronics and high-power applications of packages according to exemplary embodiments of the present disclosure.

In an alternative embodiment, the package may be free of a thermal interface material (TIM) between the output surface delimited by the functional filling medium and a heat sink or the like. In particular when the functional filling medium is provided sufficiently adhesive, a TIM may even be omitted (to guarantee the absence of air voids). This may enable a package to be manufactured in a simple and compact manner.

In an embodiment, the electronic component comprises at least one pad which is electrically coupled with at least one electrically conductive layer structure of the stack. Such a pad may be an electrically conductive terminal which may provide for an electric interconnection of the at least one active electronic component and a wiring pattern of the component carrier, for instance a printed circuit board. By taking this measure, it may be ensured that the electronic component functionally cooperates with the electrically conductive layer structure(s) of the stack and/or with at least one optional further electronic component of the package and/or with an electronic periphery of the package.

In an embodiment, the at least one pad is electrically coupled with the at least one electrically conductive layer structure by at least one bond wire, by a ball grid array and/or by a land grid array. In particular, one or more bond wires may be interconnected between a respective exposed pad of the active electronic component on the one hand and an exposed electrically conductive layer structure of the stack. The bond wire(s) may extend, partially or entirely, within the cavity. It is also possible that a bottom of the cavity is provided with one or more electrically conductive surfaces of the at least one electrically conductive layer structure being interconnected with the one or more pads of the at least one active electronic component, in particular by plugging or by a solder structure directly in between. In one embodiment, the bottom of the cavity may be configured as a grid array interface, for instance as a ball grid array interface or a land grid array interface. Land Grid Array (LGA) and Ball Grid Gray (BGA) are both component assembly technologies. They basically define how the electronic component will actually be mounted, in particular at a bottom surface defining the cavity. Essentially, the most basic difference between the two is that an LGA based component can be removed from the stack and can also be replaced. A BGA based component, however, is generally soldered on the bottom of the cavity in the stack and thus cannot be removed or replaced.

In an embodiment, at least part of a sidewall delimiting the cavity is lined with a functional lining, in particular a metallic lining. More specifically, the vertical surface portions delimiting the cavity may be covered partially or entirely with a metallic layer, for instance plated copper. For example, such a metallic layer covering the cavity may contribute to heat removal out of the package, may shield the component from external radio-frequency signals, may contribute to the spatial definition of a resonator for radio-frequency electromagnetic radiation, etc. Also, the bottom surface and/or a top surface of the cavity may be lined with a metallic layer, in addition or as an alternative to the lining of the sidewalls.

In an embodiment, the functional lining is configured for shielding electromagnetic radiation, in particular radio-frequency electromagnetic radiation, from propagating between an interior and an exterior of the cavity. Advantageously, such a metallic layer may shield electromagnetic radiation from propagating between an interior and an exterior of the cavity. Consequently, the electrical reliability of the package can be further improved. By providing said shielding function by the functional lining, the functional filling medium may be freely engineered for providing a further function. This increases the freedom of design.

In an embodiment, the package comprises a heat sink on or above the output surface and thermally coupled with the functional filling medium. For instance, such a heat sink may comprise a (for example metallic) cooling plate attached to the output surface of the functional filling medium (or attached to a thermal interface material in between) for providing a highly thermally conductive path from the encapsulated active electronic component in the laminated layer stack through the functional filling medium up to the heat sink and out of the package. For example, a plurality of cooling fins may be integrally formed with the cooling plate so that the thermal exchange surface between the heat sink and the surrounding of the package may be further improved. Additionally or alternatively, it is also possible that a cooling fluid (such as a liquid, for instance water) is guided through one or more channels of the cooling plate for promoting cooling. In an embodiment, the package comprises a heat sink on or above the output surface and directly thermally coupled with the functional filling medium or thermally coupled with the functional filling medium via a thermal interface material.

In an embodiment, the package comprises a further heat sink on a main surface of the stack opposing the output surface. Highly advantageously, both opposing main surfaces of the stack may be equipped with a respective heat sink (which may each be embodied as described in the preceding paragraph) so that two heat removal paths may be formed from the active electronic component out of the package and extending in opposite directions. Advantageously, such an approach may allow to achieve double-sided cooling of the package, in particular of a PCB-type package with active electronic component encapsulated by a functional filling medium.

In an embodiment, at least part of the functional filling medium is optically transparent. In particular, the functional filling medium may be optically transparent for electromagnetic radiation in the visible range (i.e., for visible light), in the ultraviolet (UV) range (i.e., for UV radiation) and/or in the infrared (IR) range (i.e., for IR radiation). This may allow to guide optical signals through the optically transparent functional filling medium or the optically transparent part thereof. At the output surface, said optical signals may propagate outside of the package (when emitted by the encapsulated electronic component) and/or into the package (when emitted by an entity apart from the package for detection by the encapsulated electronic component). It is also possible that an optical communication partner device for the encapsulated active electronic component is mounted on the output surface of the functional filling medium, for instance an optical sensor (when the active electronic component is an optical emitter), and/or an optical emitter (when the active electronic component is an optical sensor). Hence, the package may be advantageously an optoelectronic package.

In an embodiment, the package comprises a guide inlay in the cavity defining, together with the optically transparent functional filling medium, an optical waveguide cooperating optically with the electronic component. For example, such a guide inlay may be a three dimensionally (3D) printed member or an injection molding part which can be manufactured with low effort, and which can be easily inserted into the cavity. The remaining empty spaces of the cavity may then be filled partially or entirely with the optically transparent functional filling medium.

In an embodiment, a bottom portion of the functional filling medium surrounding a bottom portion of the electronic component including at least one pad thereof is dielectric, wherein a top portion of the functional filling medium comprises another material than the bottom portion of the functional filling medium (and surrounds a top portion of the electronic component). More generally, different regions of the cavity may be filled with at least two different kinds of functional filling medium. This may enable a spatial adjustment of the properties of the functional filling medium to the particularities of the package design in different cavity regions. For instance, a bottom-sided portion of the functional filling medium may be designed to properly function as an underfill for the electronic component. A top-sided portion of the functional filling medium may be designed to functionally collaborate with a portion of the electronic component having a critically high heat load (so that the corresponding functional filling medium should have a high thermal conductivity) or having an optical signal transmission function (so that the corresponding functional filling medium should be optically transparent). By filling different portions of the cavity with different types of functional filling medium, the functionality of the package may be further refined. This may also make it possible that at least two functions are provided by the functional filling medium, for example a first function by a first type of functional filling medium in a first region of the cavity and a second function by a second type of functional filling medium in a second region of the cavity.

In an embodiment, the cavity is dimensioned and the functional filling medium and the electronic component are arranged in the cavity so that heat generated by the electronic component is spatially spread towards an outside of the cavity, in particular over a spatial angle (which may also be denoted as an angular range) in a range from 60° to 120°, more particularly over a spatial angle in a range from 75° to 105°, most preferably in a range from 85° to 95°. A preferred heat spreading angle may be ±45° (i.e., corresponding to an angular range of 90°) from a vertical direction or from a direction being perpendicular to a planar output surface of the functional filling medium. It has been found that the above-mentioned spatial and angular ranges are an appropriate choice for ensuring proper heat spreading. Thus, the thermal performance of the package may be enhanced when selecting the spatial angle in the above-mentioned ranges.

In an embodiment, the functional filling medium is configured for shielding electromagnetic radiation, in particular radiofrequency electromagnetic radiation, from propagating between an interior and an exterior of the cavity. Hence, the functional filling medium itself may be configured so that electromagnetic radiation is absorbed and/or reflected by the functional filling medium. For example, this may be accomplished by appropriate (in particular metallic or magnetic) filler particles. It is also possible that the functional filling medium is a (in particular metallic or magnetic) paste providing such a shielding function.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In an embodiment, the component carrier is an integrated circuit substrate. In the context of the present application, the term “integrated circuit substrate” (IC substrate) may particularly denote a component carrier having a size and a pitch adjusted to the requirements of an integrated circuit component (in particular the control chip) mounted thereon. An IC substrate may be a, in relation to a PCB, comparably small component carrier onto which one or more integrated circuit components may be mounted and that may act as a connection body between one or more chip(s) and a PCB. For instance, an IC substrate may have substantially the same size as an electronic component to be mounted thereon (for instance in case of a Chip Scale Package (CSP)). In another embodiment, the IC substrate may be larger than the assigned component (for instance in a flip chip ball grid array, FCBGA, configuration). More specifically, an IC substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the IC substrate and can be used to provide electrical, thermal and/or mechanical connections of housed components or unhoused components (such as bare dies), particularly of IC chips, with a printed circuit board or interposer. A dielectric part of an IC substrate may be composed of resin with reinforcing particles (such as reinforcing spheres, in particular glass spheres). A pitch, i.e., a distance between corresponding edges of two adjacent metal structures of an IC substrate may be not more than 150 μm, in particular not more than 100 μm. In contrast to this, a pitch of a PCB may be at least 200 μm, in particular at least 300 μm.

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g., based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g., fibers impregnated with the above-mentioned resins is called prepreg. These prepregs are often named after their properties, e.g., FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular coated with supra-conductive material or conductive polymers, such as graphene or poly(3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semi-conductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also, nickel-free materials for a surface finish may be used, in particular for high-speed applications. Examples are ISIG (Immersion Silver Immersion Gold), and EPAG (Electroless Palladium Autocatalytic Gold).

The aspects defined above and further aspects of the present disclosure are apparent from the examples of embodiment to be described hereinafter and are explained with reference to these examples of embodiment.

### BRIEF DESCRIPTION OF THE DRAWINGS

FIG. 1 illustrates a cross-sectional view of a package according to an exemplary embodiment of the present disclosure.

FIG. 2 illustrates a cross-sectional view of a package according to another exemplary embodiment of the present disclosure.

FIG. 3 illustrates a cross-sectional view of a package according to another exemplary embodiment of the present disclosure.

FIG. 4 illustrates a model for simulating operation of a package according to an exemplary embodiment of the present disclosure.

FIG. 5 illustrates a cross-sectional view of a package according to another exemplary embodiment of the present disclosure.

FIG. 6 illustrates a cross-sectional view of a package according to another exemplary embodiment of the present disclosure.

FIG. 7 illustrates a cross-sectional view of a package according to another exemplary embodiment of the present disclosure.

FIG. 8 illustrates a cross-sectional view of a package according to another exemplary embodiment of the present disclosure.

FIG. 9 illustrates a cross-sectional view of a package according to another exemplary embodiment of the present disclosure.

### DETAILED DESCRIPTION OF ILLUSTRATED EMBODIMENTS

The illustrations in the drawings are schematically presented. In different drawings, similar or identical elements are provided with the same reference signs.

Before referring to the drawings, exemplary embodiments will be described in further detail, some basic considerations will be summarized based on which exemplary embodiments of the present disclosure have been developed.

According to an exemplary embodiment of the present disclosure, a (preferably semiconductor-type) package is provided which may be based on a component carrier (such as a PCB or an IC substrate) composed of stacked (and preferably laminated) layer structures. At least one active electronic component, such as a semiconductor chip comprising a transistor and/or another active integrated circuit element, may be assembled in a cavity (preferably at the bottom of the cavity) of the layer stack. Advantageously, a functional filling medium may be inserted in the cavity, for instance for contacting or even entirely surrounding the component. The functional filling medium is specifically functionalized so as to provide at least one function in addition to serving as filling medium. A functional interaction between the component and the functional filling medium thereon may provide a functional output at an output surface of the functional filling medium which may correspond to an external surface portion of the stack with its filled cavity. At said output surface delimited at least partially by the functional filling medium, the functional output of said active component may be provided or supplied to a destination (such as ambient air or a further member). Said destination may be a physical body being in direct physical contact with at least part of said output surface, for instance a heat sink receiving a heat output dissipated from the component via the functional filling medium. It is also possible that said destination is air or even a vacuum through which electromagnetic radiation propagates which originates from the component (for instance an optical signal or a high-frequency signal emitted by the component and propagating through the functional filling medium being transparent for said electromagnetic radiation). In the latter example, said output of the active electronic component may be a signal output. By encapsulating the component by the filling medium in the cavity, the space consumption of the package may be kept small. The provision of a functional filling medium which provides at least one function other than encapsulating the component and the provision of the functional output of an interaction with the component at an output surface of the functional filling medium leads to a higher degree of functionality in a simple way. Thus, a cavity fill may also lead to an encapsulation of the component.

According to an exemplary embodiment, a cavity may be formed in the stack by embedding a release layer with poorly adhesive properties in the stack. For example, such a release layer may be made of a waxy material or of polytetrafluoroethylene (PTFE). Thereafter, a circumferentially closed cut may be created in the stack which cuts out a stack piece being delimited at a bottom surface by the release layer. Such a cutting process may be carried out, for instance, by laser cutting or mechanically cutting. After taking out the separated stack piece from the remainder of the stack, a cavity remains. Alternatively, a cavity may be formed by grinding, routing and/or etching.

After having created one or more cavities in the stack, the active electronic component (in particular a semiconductor chip) may be inserted in the cavity. Preferably thereafter (or alternatively before chip assembly in the cavity), remaining empty spaces of the cavity may be filled partially or entirely with functional filling medium. Preferably, said functional filling medium may be a thermally enhanced filler material which provides the additional function of a heat removal capability for removing heat created by the active electronic component during operation of the package. The functional filling medium may also have adhesive properties for good mechanical interaction to different materials, e.g., component and/or stack.

In such a design of exemplary embodiments, walls of the cavity may replace a conventional dam structure, which may significantly contribute to the compactness of the package. Furthermore, the cavity may be filled with epoxy resin which may be enriched with one or more functional additives or functional filler particles to cover the active electronic component partially or entirely and to provide an additional functionality to the package.

In particular, filling the cavity at least partially with a thermal conductivity enhancing functional filling medium may help to reduce the thermal resistance (Rₜₕ) from the (preferably chip-type) active electronic component to ambient in addition to advantages of miniaturization and encapsulation resulting from the cavity formation and filling process.

A process of an exemplary embodiment of the present disclosure may comprise forming a cavity (preferably using the above-described approach of an embedded release layer) and filling the cavity with a functional filling medium (which may be based on a resin, preferably including functional additives and/or filler particles). Preferably, the above-described cavity provided to house the active electronic component may be filled with a thermally enhanced filler material. The properties (in particular the value of the thermal conductivity) of the functional filling medium may be selected for reducing thermal resistance from the active electronic component to the ambient. Filler materials of different thermal conductivity have been simulated. Results show that filler material with higher thermal conductivity assist significantly in reducing the thermal resistance between the chip and an ambient environment.

Advantageously, the cavity may be dimensioned for providing advantageous or even optimum properties in terms of heat spreading. The cavity geometry may be selected for properly adjusting a spatial range of heat spreading, as described above.

In an embodiment, a thermal interface material (TIM) may be provided between the functional filling medium and a heat sink, for instance may be attached to the output surface of the functional filling medium. This may further promote thermal coupling between the active electronic component embedded in the functional filling medium and the heat sink.

In another embodiment, a TIM between heat sink and PCB-type component carrier can be omitted, when a thermally enhanced adhesive filler material is used as functional filling medium. This promotes a simple and compact design.

Exemplary embodiments of the present disclosure have advantages. Firstly, a hardware miniaturization of the package may be achieved by substituting a conventional surface mounted dam structure by a cavity formed inside of a component carrier-type stack. Furthermore, an encapsulation process may be rendered highly efficient when simply filling up a cavity in which the active electronic component has previously been assembled. Exemplary embodiments may further reduce or even eliminate a need to precisely control a resin filling process, compared with a conventional dam process. The amount of used filler material may be reduced. Moreover, an improved heat transfer from the encapsulated active component to the ambient of the package may be achieved. Furthermore, a thermal resistance at the junction between the package and an ambient may be reduced as well.

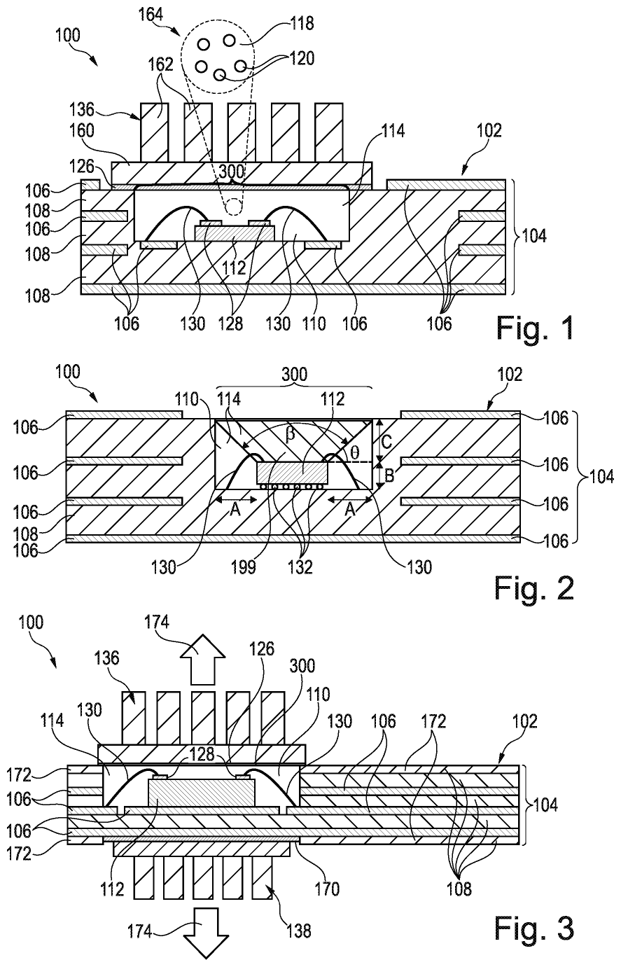

FIG. 1 illustrates a cross-sectional view of a package 100 according to an exemplary embodiment of the present disclosure.

The shown package 100 comprises a component carrier 102. Component carrier 102 may be an integrated circuit (IC) substrate or a printed circuit board (PCB). The component carrier 102 may comprise a laminated layer stack 104 comprising electrically conductive layer structures 106 and electrically insulating layer structures 108. For example, the electrically conductive layer structures 106 may comprise patterned metal layers (such as patterned copper foils or patterned deposited copper layers) and vertical through connections, for example copper filled vias, which may be created by drilling and plating. The electrically insulating layer structures 108 may comprise a respective resin (such as a respective epoxy resin), preferably comprising reinforcing particles therein (for instance glass fibers or glass spheres). For example, the electrically insulating layer structures 108 may be made of FR4. The electrically insulating layer structures 108 may also comprise resin layers being free of glass (in particular glass fibers).

As shown in FIG. 1, a blind hole, recess or cavity 110 is formed in an upper portion of the stack 104 so as to extend vertically into the stack 104 from an upper main surface thereof. This may be done by embedding a release layer (not shown) of a poorly adhesive material inside of the stack 104 and by removing a piece of the stack 104 by creating a circumferential vertical cut up to the release layer. Thereafter, a separated piece of stack 104 may be taken out of stack 104 so that the cavity 110 remains in the stack 104 in a region from which the piece of the stack 104 has been taken out.

After having formed the cavity 110, an active electronic component 112 may be assembled in the cavity 110. For instance, the active electronic component 112 may be placed on a horizontal bottom surface of the cavity 110, for instance on a spot of adhesive (not shown). In the illustrated configuration, the active electronic component 112 has two electrically conductive pads 128 at an upper main surface. Descriptively speaking, the active electronic component 112 is arranged face up according to FIG. 1. Alternatively, the active electronic component 112 may be arranged face down, i.e., with electrically conductive pads 128 at its lower main surface. For instance, such a configuration is shown in FIG. 5. In yet another embodiment, it is also possible that the electronic component 112 has pads 128 at both opposing main surfaces thereof (see for example FIG. 2). For example, the active electronic component 112 may be a semiconductor chip having at least one monolithically integrated circuit element therein. For instance, the active electronic component 112 may be a transistor chip, i.e., a chip having at least one monolithically integrated transistor, such as a MOSFET (metal oxide semiconductor field effect transistor). It is also possible that the active electronic component 112 is a semiconductor power chip. Other semiconductor chips providing a controlling function, for instance comprising one or more diodes, may be used as well as active electronic component 112.

More generally, electronic component 112 of FIG. 1 may be an electric chip. In the context of the present application, the term “electric chip” may particularly denote a chip having an electric functionality. For example, the electric chip may be configured for processing an electric signal. It is also possible that the electric chip comprises a drive functionality or a control functionality. The electric chip may also be a processor.

As shown as well in FIG. 1, each of the electrically conductive pads 128 of the active electronic component 112 is electrically coupled with a respective section of the electrically conductive layer structure 106 of the stack 104 forming part of the bottom of the cavity 110. Said electric coupling is accomplished, in the embodiment of FIG. 1, by a respective metallic bond wire 130 extending inside of the cavity 110 between an assigned pad 128 and an assigned section of the electrically conductive layer structure 106 exposed at the bottom of the cavity 110.

After having established the described electric connection between the active electronic component 112 and the component carrier 102, a functional filling medium 114 may be inserted into the cavity 110 for completely filling up the cavity 110. Thus, an upper main surface of the functional filling medium 114 may form a continuous step-less transition to the stack 104, in the shown embodiment next to the uppermost electrically insulating layer structure 108 of the stack 104. Hence, the functional filling medium 114 completely fills up the cavity 110 and fully circumferentially surrounds the encapsulated active electronic component 112. In other words, the electronic component 112 is entirely embedded in the functional filling medium 114 according to FIG. 1. This ensures a highly efficient thermal coupling between the electronic component 112 and the functional filling medium 114.

As indicated by its designation, the functional filling medium 114 provides a specific function rather than only serving as an encapsulation of the active electronic component 112. In the embodiment of FIG. 1, the functional filling medium 114 has an extraordinarily high thermal conductivity, most preferably in a range from 4 W/m·K to 13 W/m·K. Thus, the function provided by the functional filling medium 114 in FIG. 1 is the provision of a pronounced heat removal capability. More specifically, when the active electronic component 112 generates heat during operation of the package 100, said heat is transferred efficiently from the electronic component 112 to the highly thermally conductive functional filling medium 114 and from there to an outside environment surrounding the package 100.

As shown, said functional filling medium 114 extends up to an external surface of the cavity-filled stack 104 and defines a stack-external output surface 300. Since the heat is conducted from the active electronic component 112 through the highly thermally conductive functional filling medium 114 up to the output surface 300, the heat from the active electronic component 112 to be dissipated is output from the cavity 110 at the output surface 300. Thus, the heat originating from electronic component 112 is provided as a functional output of the thermally conductive functional filling medium 114 at the output surface 300. Thus, the thermal output of said active electronic component 112 is transmitted toward said output surface 300 by means of the functional filling medium 114.

Still referring to FIG. 1, package 100 comprises a layer-shaped thermal interface material (TIM) 126 which is attached directly on top of the functional filling medium 114 and on top of a connected portion of the stack 104. More precisely, the thermal interface material 126 is attached to the output surface 300 with direct physical contact to the functional filling medium 114. The presence of the thermal interface material 126 further improves the thermal coupling of the active electronic component 112 via the functional filling medium 114, the thermal interface material 126 and finally a (in particular metallic or ceramic) heat sink 136 attached to the thermal interface material 126. Consequently, the thermal interface material 126 (directly) and the heat sink 136 (indirectly) functionally interact with the output surface 300 of the functional filling medium 114. Thus, the heat sink 136 above the output surface 300 is thermally coupled with the functional filling medium 114. As shown, the heat sink 136 comprises a highly thermally conductive plate 160 and a plurality of cooling fins 162 extending therefrom. While the thermally conductive plate 160 is in direct physical contact and thermal interaction with the thermal interface material 126, the cooling fins 162 provide an increased thermal exchange surface with the environment of the package 100. Hence, the package configuration according to FIG. 1 provides a highly efficient heat removal function. A specific advantage of the provision of a thermal interface material 126 is that it may function as a bridge between rough surfaces of the heat sink 136 and the functional filling medium 114 (in particular when comprising a high amount of filler particles 120, described below in further detail).

In order to achieve the high thermal conductivity as explained above and as shown in detail 164, the functional filling medium 114 is provided as a matrix 118 with filler particles 120 embedded therein. For instance, matrix 118 comprises an epoxy resin. For example, the functional filling medium 114 is dielectric and has a high thermal conductivity. These requirements can be achieved by embodying the filler particles 120 as ceramic particles, for instance made of aluminum nitride, silicon oxide and/or aluminum oxide. This ensures a high electric reliability thanks to the enhancement of the dielectric surrounding of the active electronic component 112 and guarantees simultaneously a high thermal conductivity of the functional filling medium 114. For instance, the filler particles 120 may be provided in an amount of 90 weight percent (or more) in relation to the weight of the entire functional filling medium 114. A preferred particle size may be in a range from 1 nm to 500 μm, in particular from 1 μm to 75 μm. A particle size distribution may occur. In a preferred embodiment, all particles may have the same size. Although not shown in FIG. 1, the functional filling medium 114 may comprise one or more further additives for fine-tuning its properties.

In package 100 according to FIG. 1, the cavity 110 is used to house the electronic component 112. In the illustrated design, walls of the cavity 110 may replace a conventional dam structure. As shown, cavity 110 is filled with the functional filling medium 114 embodied as a thermally enhanced filler epoxy resin to cover the electronic component 112.

In an embodiment not shown in FIG. 1, the functional filling medium 114 in the cavity 110 may optionally take over the functionality of the thermal interface material 126. In such an embodiment, the TIM layer can be eliminated in order to achieve a simple and compact configuration. Furthermore, this may help to reduce the thermal resistance (Rₜₕ) from the chip-type electronic component 112 to ambient in addition to advantages of miniaturization and encapsulation.

The combined advantages of miniaturization and encapsulation can be achieved by modifying a conventional dam-and-fill process by a synergetic combination with a cavity formation approach. In the shown design, walls of the cavity 110 may replace a conventional dam structure, and the cavity 110 can be filled with an epoxy resin-based functional filling medium 114 to cover the electronic component 112. This filling may also contribute to overcome the conventional issue of exposed copper areas that may result from cavity creation. Hence, undesired phenomena such as corrosion of copper may be prevented as well by the filling of the cavity 110 by a functional filling medium 114. In addition to the above-mentioned advantages, the technique of manufacturing package 100 according to FIG. 1 may also improve the heat transfer from the chip to the ambient.

FIG. 2 illustrates a cross-sectional view of a package 100 according to another exemplary embodiment of the present disclosure.

The embodiment of FIG. 2 differs from the embodiment of FIG. 1 in particular in that, according to FIG. 2, pads 128 of the active electronic component 112 are provided at a bottom surface thereof and are electrically coupled with an electrically conductive layer structure 106 of the stack 104 exposed at the bottom of the cavity 110 by a ball grid array 132. More specifically, said pads 128 may be solder-connected with respective sections of the exposed electrically conductive layer structure 106 via solder balls of ball grid array 132. Additionally or alternatively, bond wires 130 may be optionally provided according to FIG. 2 for connecting pads 128 on the upper side of the electronic component 112 with the exposed electrically conductive layer structure 106.

Further advantageously, the cavity 110 of the package 100 according to FIG. 2 is dimensioned and the functional filling medium 114 and the electronic component 112 are arranged in the cavity 110 so that heat generated by the electronic component 112 is spatially spread towards an outside of the cavity 110 over a spatial angle β which may be preferably selected to be in a range from 75° to 105°, more preferably in a range from 85° to 95°, and most preferably 90°. As illustrated in FIG. 2, angle β defines a spatial range over which heat is dissipated from the upper main surface of the active electronic component 112 upwardly through the highly thermally conductive functional filling medium 114 and up to the output surface 300 corresponding to the exposed surface of the functional filling medium 114.

The heat spreading angle β is defined by a symmetric angular range of ±β/2, wherein two symmetric partial ranges β/2 extend from a vertical direction perpendicular to the planar output surface 300 towards the left-hand side and towards the right-hand side. As a result, a heat spreading range 199 is defined (which is shaped as a trapezoid in the cross-sectional view of FIG. 2 and which may have a frustoconical shape in three dimensions) over which heat is spread and dissipated from electronic component 112 via output surface 300 to an exterior of the package 100.

The heat spreading angle β is correlated with an angle θ between a horizontal plane of the upper main surface of the electronic component 112 and a line connecting an upper corner of the electronic component 112 with an exterior corner between the functional filling medium 114 and the stack 104 by the equation:

β+2θ=180°

The embodiment of FIG. 2 corresponds to optimum dimensions of the cavity 110 in terms of heat spreading efficiency.

In order to harvest complete advantages of miniaturization and encapsulation, it may be advantageous to calculate optimum dimensions of the cavity structure. Larger values of the cavity dimensions may lead to more filler material in the cavity 110 which in turn hinders the objective of reducing the thermal resistance. The cavity dimensions are calculated assuming that the angle of inclination of the heat transfer path θ with the cavity wall should be 45° for an optimal heat transfer as shown in the figure below. This corresponds to an optimum value of the angle β of 90°. The angle of inclination of the heat transfer path θ with the cavity wall can be 45° for an optimal heat transfer.

Applying this optimization condition (θ=45°) to the figure, the following equation may be derived:

tan 45°=C/A=>C=A

An optimal height Hₒₚₜ of the cavity 110 is given as,

Hₒₚₜ=B+C=B+A

where:
A is the horizontal distance of the electronic component 112 from the cavity wall;
C is the distance between the top surface of the electronic component 112 and the cavity 110;
B is the height of the electronic component 112 (including solder balls).

In a generic formulation, the height of the cavity 110 may be preferably the sum of a height (B) of the electronic component 112 plus a horizontal distance (A) of sidewalls of the electronic component 112 from sidewalls delimiting the cavity 110. Good results may still be achieved when the height of the cavity 110 differs from said sum by not more than ±20%, preferably by not more than ±10%.

Designing the package 100 accordingly provides excellent results in terms of heat spreading and simplicity of the manufacturing process. Briefly, the mentioned design rule may avoid both an under-dimensioning and an over-dimensioning of the cavity 110. An over-dimensioning may involve an excessive amount of functional filling medium 114. An under-dimensioning might not provide a sufficiently good thermal performance.

FIG. 3 illustrates a cross-sectional view of a package 100 according to another exemplary embodiment of the present disclosure.

The embodiment of FIG. 3 differs from the embodiment of FIG. 1 in particular in that, in the embodiment of FIG. 3, package 100 comprises a top-sided first heat sink 136 and a bottom-sided second heat sink 138. The first heat sink 136 may be arranged on the thermal interface material 126 and thus above the output surface 300 or directly on the output surface 300 (when a thermal interface material is omitted) and thermally coupled with the functional filling medium 114. The further or second heat sink 138 can be arranged on a main surface of the stack 104 opposing the output surface 300. For instance, the second heat sink 138 may be attached to a metallic surface finish 170 (such as ENIG, or alternatively to a thermal interface material, not shown) on the bottom main surface of stack 104. According to FIG. 3, a patterned solder mask 172 is provided on both opposing main surfaces of the stack 104 apart from the respective heat removal path. As indicated by arrows 174 in FIG. 3, double-sided cooling can be achieved by the shown configuration, i.e., a first heat removal path from electronic component 112 to the first heat sink 136 and a second heat removal path from the electronic component 112 to the second heat sink 138. Hence, package 100 according to FIG. 3 provides an excellent thermal performance.

Thus, it is possible to achieve double sided cooling with the embodiment of FIG. 3. The thermal performance of package 100 may be further improved by using thermally enhanced prepreg as interior electrically insulating layer structures 108. More generally, a thermally enhanced electrically insulating layer structure 108 of a package 100 according to any embodiment of the present disclosure may be provided with a thermal conductivity in a range from 3 to 5 W/m·K, which may be significantly higher than using ordinary prepreg.

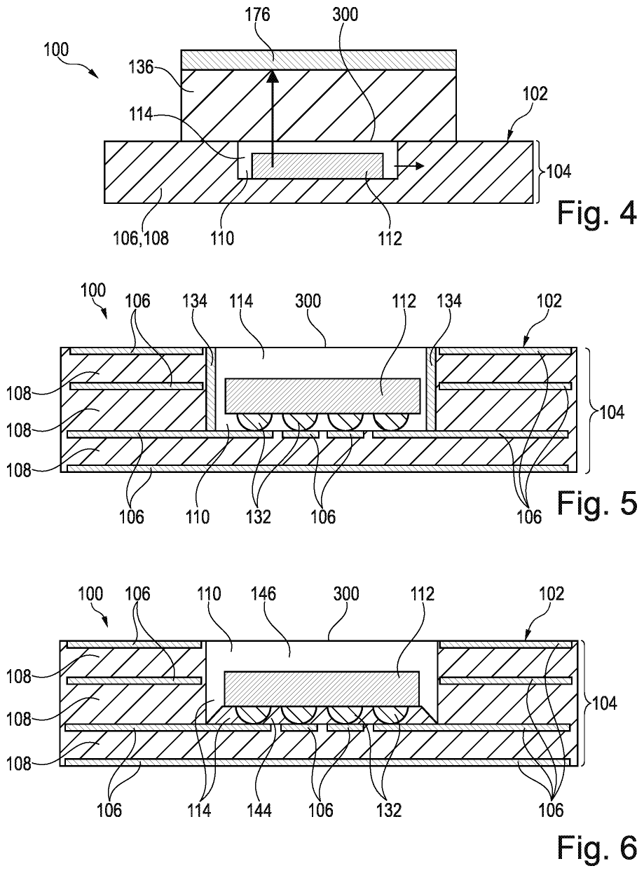

FIG. 4 illustrates a model for simulating operation of a package 100 according to an exemplary embodiment of the present disclosure. The model simulated according to FIG. 4 substantially corresponds to the embodiment of FIG. 2 described above.

A simulation model has been created using the software “CST Studio Suite 2021” (for example, Flotherm, Simscale, ANSYS, ElectroFlo, COMSOL may be used as well). Said simulation model of package 100 is composed of an electronic component 112 placed inside a cavity 110 as shown in FIG. 4. Materials of different thermal conductivity (λ) are considered as the functional filling medium 114 for the cavity 110. Reference sign 176 indicates a thermal wall. It has been inferred from the simulation results that the thermal resistance (Rₜₕ) between the electronic component 112 and heat sink 136 is highly reduced by using a functional filling medium 114 of higher thermal conductivity:

Rₜₕ(Material with λ1 in cavity):26.5° C./W

Rₜₕ(Material with λ2 in cavity):2.09° C./W

λ1=0.3 W/m·K;λ2=6 W/m·K

Hence, the excellent thermal performance of package 100 according to FIG. 2 is verified by the simulation according to FIG. 4. A highly advantageous configuration of cavity 110 can be constructed with respect to the formulation explained above. The cavity 110 is then filled with materials of different thermal conductivities and the thermal resistances are calculated. The filler material with a thermal conductivity λ1=0.3 W/m·K results in a thermal resistance of 26.5° C./W and the other filler with a thermal conductivity λ2=6 W/m·K results in a thermal resistance of 2.09° C./W. It could be observed that the TIM layer can be neglected in the model as mentioned before. It is clear that a material of higher thermal conductivity should be used as the filler material to achieve the reduction in thermal resistance.

Table 1 shows a list of thermally conductive filler materials which can be advantageously used as functional filling medium 114 of a package 100 according to exemplary embodiments.

TABLE 1

| | Thermal Conductivity |
|---|---|
| Material | (W/m · K) |
| β-Si3N4 filler | 4.7 |
| Alumina filler | 6 |
| BN agglomerates | 10 |
| h-BN filler | 10.3 |
| Silicone based epoxy | 13 |

FIG. 5 illustrates a cross-sectional view of a package 100 according to another exemplary embodiment of the present disclosure.

The embodiment of FIG. 5 corresponds to the embodiment of FIG. 2 what concerns the assembly of bottom-sided pads 128 of the electronic component 112 on exposed sections of an electrically conductive layer structure 106 of the stack 104 exposed at the bottom of the cavity 110, wherein no bond wires 130 are foreseen in FIG. 5. The embodiment of FIG. 5 differs from the embodiment of FIG. 2 in particular in that, according to FIG. 5, vertical sidewalls delimiting the cavity 110 are lined with a functional lining 134 of a metal such as copper or iron.

When the sidewalls are lined with a functional lining 134 of a metal such as copper with a high thermal conductivity, said functional lining 134 may contribute additionally to an efficient heat removal out of the package 100. For example, the functional lining 134 may be formed by plating or sputtering after formation of the cavity 110 and before filling the cavity 110 with the electronic component 112 and the functional filling medium 114.

When the sidewalls are lined with a functional lining 134 of a metal such as iron, the functional lining 134 may also function for shielding radio-frequency electromagnetic radiation from propagating between an interior and an exterior of the cavity 110. A magnetic lining may be also particularly advantageous for said purpose. By the described shielding, an electronic component 112 assembled in the cavity 110 and being sensitive with respect to electromagnetic radiation (such as microwaves) may be protected from disturbing electromagnetic radiation propagating from outside of the package 100 towards package 100. Such an electromagnetic radiation may be absorbed and/or reflected by an appropriate functional lining 134 to thereby protect the electronic component 112. It may also be possible that the shielding prevents electromagnetic radiation emitted by the electronic component 112 to propagate to electromagnetic radiation sensitive electronic members in the surrounding of the package 100.

FIG. 6 illustrates a cross-sectional view of a package 100 according to another exemplary embodiment of the present disclosure.

The embodiment of FIG. 6 differs from the embodiment of FIG. 5 in particular in that, according to FIG. 6, a bottom portion 144 of the functional filling medium 114 surrounding a bottom portion of the electronic component 112 including pads 128 thereof is dielectric, whereas a top portion 146 of the functional filling medium 114 comprises another material than the bottom portion 144 of the functional filling medium 114.

For instance, the bottom portion 144 of the functional filling medium 114 may electrically decouple the pads 128 connected with the exposed electrically conductive layer structure 106 with respect to an environment. Thus, the underfill-type bottom portion 144 may ensure that there is no electric short of the electronic component 112. For instance, the underfill-type bottom portion 144 may have a thermal conductivity in a range from 0.7 W/m·K to 2.5 W/m·K, for example 1 W/m·K.

In contrast to this, the top portion 146 may have a higher thermal conductivity than the bottom portion 144 in order to define a heat removal path oriented upwardly according to FIG. 6 and extending predominantly towards the output surface 300. This may ensure a controlled heat removal path and a proper thermal performance of the package 100 according to FIG. 6. For instance, the top portion 146 may have a thermal conductivity in a range from 4 W/m·K to 13 W/m·K, for example 8 W/m·K.

Furthermore, no functional lining 134 is foreseen according to FIG. 6, although it may be present in other embodiments.

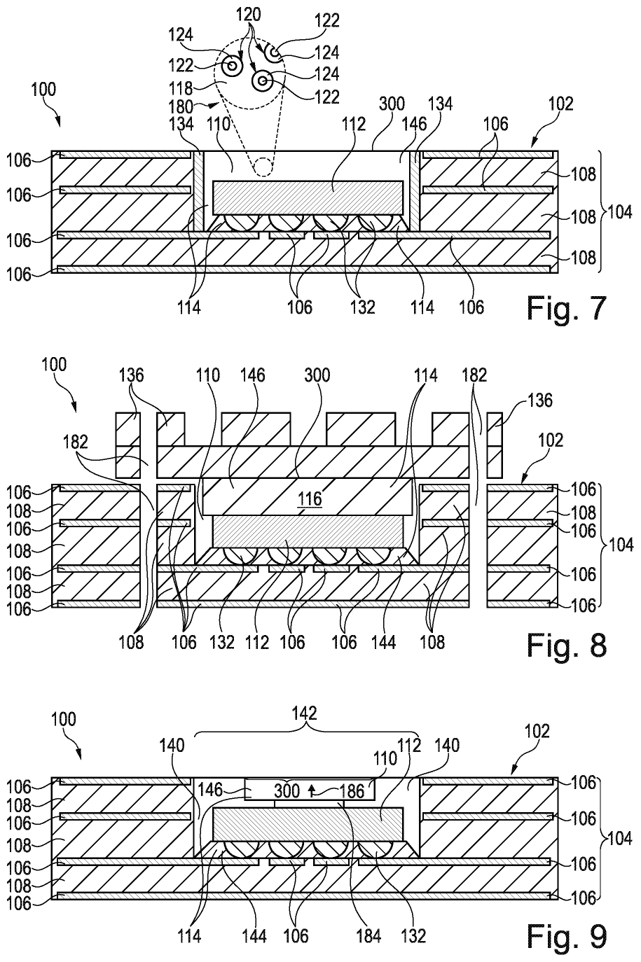

FIG. 7 illustrates a cross-sectional view of a package 100 according to another exemplary embodiment of the present disclosure.

The embodiment according to FIG. 7 differs from the embodiment according to FIG. 6 in particular that, according to FIG. 7, filler particles 120 of the top portion 146 comprise a metallic material. Thus, the functional filling medium 114 itself may be configured for shielding radiofrequency electromagnetic radiation from propagating between an interior and an exterior of the cavity 110 to thereby protect the embedded electronic component 112. Configuring the functional filling medium 114 as a shielding medium may render a plating of sidewalls with a functional lining 134 dispensable. Alternatively, as shown in FIG. 7, a functional lining 134 of the vertical sidewalls delimiting the cavity 110 may be formed additionally to the provision of the functional filling medium 114 of a metallic material for further improving the radiation shielding performance.

Now referring specifically to detail 180 of FIG. 7, the functional filling medium 114 is provided with a matrix 118 with filler particles 120 embedded therein. For instance, matrix 118 may comprise a resin, such as an epoxy resin. The filler particles 120 may comprise a metallic core 122 (for instance made of copper or iron) covered by a dielectric shell 124 (for example a ceramic or a polymer). For instance, a shell thickness may be in a range from 1 nm to 60 nm (for example for SiOx particles). In particular, a ratio between shell thickness to particle core diameter may be in a range from 5% to 200%. Such filler particles 120 may provide an excellent radiation shielding function while simultaneously contributing to efficient heat removal. A dielectric shell 124 or coating of the metallic cores 122 may ensure that the exterior surface of the particles 120 will be electrically insulating which may promote the dielectric protection function of the functional filling medium 114 for the active electronic component 112. As an alternative to the core-shell-configuration of the filler particles 120, they can also be provided as a metallic paste or as purely metallic particles.

FIG. 8 illustrates a cross-sectional view of a package 100 according to another exemplary embodiment of the present disclosure.

According to FIG. 8, the top portion 146 of the functional filling medium 114 comprises a sheet 116 (or any other kind of inlay-type filler) arranged in an upper portion of the cavity 110 above the electronic component 112 which is arranged in a lower portion of the cavity 110. As shown, the top portion 146 of the functional filling medium 114 may even protrude vertically beyond the upper main surface of the stack 104. A lower portion of the electronic component 112 is arranged inside an underfill-type bottom portion 144 of the functional filling medium 114. Hence, an intermediate part of the cavity 110 according to FIG. 8 remains empty. The only partial filling of the cavity 110 saves material of functional filling medium 114 and therefore effort, weight and volume. Covering selectively the upper main surface of electronic component 112 with a sheet of functional filling medium 114 may also properly define a heat removal path, which is in the upward direction according to FIG. 8.

A heat sink 136 attached directly to sheet 116 receives heat conducted from the electronic component 112 through sheet 116 up to the heat sink 136 and dissipates the heat towards the environment of the package 100.

As shown in FIG. 8 as well, the heat sink 136 and the stack 104 may be provided with aligned (for example through hole-type) fastening provisions 182 which may be configured to receive a fastening element (not shown), such as a screw or a bolt, for mechanically connecting the heat sink 136 with the stack 104. This may further improve the reliability of the thermal coupling.

FIG. 9 illustrates a cross-sectional view of a package 100 according to another exemplary embodiment of the present disclosure.

The embodiment of FIG. 9 differs from the embodiment of FIG. 6 in the configuration of the functional filling medium 114 and in the configuration of the electronic component 112.

According to FIG. 9, a bottom portion 144 of the functional filling medium 114 surrounding a bottom portion of the electronic component 112 including pads 128 thereof is dielectric and may be an underfill, whereas a top portion 146 of the functional filling medium 114 comprises another material than the bottom portion 144 of the functional filling medium 114 and may be optically transparent in the illustrated embodiment.

According to FIG. 9, electronic component 112 may be an optical chip. In the context of the present application, the term “optical chip” may particularly denote a chip having an optical functionality. In particular, such an optical chip may be a chip configured for receiving an optical signal, and more particularly for converting the received optical signal into an electric signal by an electrooptical converter (such as a photodiode). The optical chip may also have processing capability for processing an optical signal and/or an electric signal to or from which the optical signal can be derived by the optical chip. The optical chip may be an electro-optical chip, in particular providing an optical functionality of an electro-optical system. In particular, the optical chip may also have an integrated semiconductor laser diode and/or an amplifier. Hence, examples of integrated circuit elements of an optical chip may be a photodiode and/or a laser diode. For example, integrated group III-V devices may be implemented in the optical chip, for example at least one laser, at least one amplifier and/or at least one photodiode.

Again, referring to FIG. 9, the electronic component 112 embodied as optical chip may comprise an optically active element 184 (which may also be denoted as optical interface), such as an optical emitter (for example a light emitting diode) for emitting light. Consequently, light may propagate from the optically active element 184 of the electronic component 112 to an optical communication partner device (not shown) outside of the package 100 (or vice versa). In order to support said light propagation, the top portion 146 of the functional filling medium 114 may be configured to be optically transparent for visible light emitted by the optically active element 184.

As shown as well, package 100 according to FIG. 9 comprises a guide inlay 140 arranged in the cavity 110 and having a bottom-sided recess as well as a top-sided recesses for accommodating the bottom-sided electronic component 112 as well as the top-sided part of the functional filling medium 114, respectively. For example, the guide inlay 140 may be a 3D-printed member or an injection molded member. Preferably, the guide inlay 140 is made of an optically opaque material through which light cannot propagate. Consequently, together with the optically transparent part of the functional filling medium 114, the guide inlay 140 defines an optical waveguide 142 cooperating optically with the electronic component 112.

As shown, the output surface 300 functions for providing an optical signal which may be generated by the electronic component 112 for optical transmission to an optical communication partner device (not shown) along a main optical path 186.

Sidewalls of the guide inlay 140 accommodating the optically transparent top portion 146 of the functional filling medium 114 and accommodating the optically active element 184 may provide for optical guidance.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures described above. Instead, a multiplicity of variants are possible which variants use the solutions shown and the principle according to the disclosure even in the case of fundamentally different embodiments.

1. A package, comprising:
a component carrier comprising a stack with at least one electrically conductive layer structure and/or at least one electrically insulating layer structure;
a cavity in the stack;
an active electronic component in the cavity; and
a functional filling medium filling at least part of the cavity, said functional filling medium extending up to an external surface of the stack for defining an output surface and configured to transmit at least one output of said active electronic component toward said output surface.

2. The package according to claim 1, wherein the electronic component is entirely embedded in the functional filling medium.

3. The package according to claim 1, wherein the functional filling medium comprises a sheet arranged in an upper portion of the cavity above the electronic component arranged in a lower portion of the cavity.

4. The package according to claim 1, wherein the functional filling medium is thermally conductive.

5. The package according to claim 1, wherein the functional filling medium comprises a matrix with filler particles embedded therein.

6. The package according to claim 5, wherein the filler particles comprise a metallic material.

7. The package according to claim 1, wherein the functional filling medium is dielectric.

8. The package according to claim 1, comprising a thermal interface material interacting with the output surface of the functional filling medium and/or being arranged on an exterior surface of the stack.

9. The package according to claim 1, wherein the active electronic component comprises at least one pad which is electrically coupled with at least one electrically conductive layer structure.

10. The package according to claim 9, wherein the at least one pad is electrically coupled with the at least one electrically conductive layer structure by at least one bond wire, by a ball grid array and/or by a land grid array.

11. The package according to claim 1, wherein at least part of a sidewall delimiting the cavity is lined with a functional lining.

12. The package according to claim 11, wherein the functional lining is configured for shielding electromagnetic radiation from propagating between an interior and an exterior of the cavity.

13. The package according to claim 1, comprising a heat sink on or above the output surface and thermally coupled with the functional filling medium.

14. The package according to claim 13, comprising a further heat sink on a main surface of the stack opposing the output surface.

15. The package according to claim 1, wherein at least part of the functional filling medium is optically transparent.

16. The package according to claim 15, further comprising:
a guide inlay in the cavity defining, together with the optically transparent functional filling medium, an optical waveguide cooperating optically with the electronic component.

17. The package according to claim 1, wherein a bottom portion of the functional filling medium surrounding a bottom portion of the electronic component including at least one pad thereof is dielectric, and wherein a top portion of the functional filling medium comprises another material than the bottom portion of the functional filling medium.

18. The package according to claim 1, wherein the cavity is dimensioned and the functional filling medium and the electronic component are arranged in the cavity so that heat generated by the electronic component is spatially spread towards an outside of the cavity.

19. The package according to claim 1, wherein the functional filling medium is configured for shielding electromagnetic radiation from propagating between an interior and an exterior of the cavity.

20. A method of manufacturing a package, comprising:
providing a component carrier comprising a stack with at least one electrically conductive layer structure and/or at least one electrically insulating layer structure;
forming a cavity in the stack;
arranging an active electronic component in the cavity; and
filling at least part of the cavity with a functional filling medium, said functional filling medium extending up to an external surface of the stack for defining an output surface and configured to transmit at least one output of said active electronic component toward said output surface.
